(19) United States
(12) Patent Application Publication
(10) Pub. No.: US 2016/0041395 A1
(43) Pub. Date: Feb. 11, 2016

(54) WEARABLE APPARATUS

(71) Applicant: SEIKO EPSON CORPORATION, Tokyo (JP)

(72) Inventor: Hideaki YAJIMA, Chino-shi (JP)

(21) Appl. No.: 14/806,083

(22) Filed: Jul. 22, 2015

(30) Foreign Application Priority Data
Aug. 8, 2014 (JP) 2014-162230

(51) Int. Cl. G02B 27/01; H05K 5/00

(52) U.S. Cl. CPC G02B 27/0176; H05K 5/0017; H05K 5/0086; G02B 2027/0178

(57) ABSTRACT

A wearable apparatus includes a display panel in which a display portion is formed on a first face of a substrate, a housing, and a panel frame supporting the display panel and transferring heat from the display panel to the housing.

### BACKGROUND

1. Technical Field

The present invention relates to a wearable apparatus.

2. Related Art

In recent years, as a wearable apparatus, a head mount display (hereinafter, referred to as an HMD) has been proposed. As such an HMD, an HMD mounting a display panel including an organic EL element is known (for example, refer to JP-A-2013-48394). In a case where the organic EL element is used as a display panel, it is important to enhance the heat radiation properties of the display panel in order to solve problems such as a degradation in display characteristics due to the heat generation or a degradation in mounting reliability.

By the way, since the mountability is valued in the HMD, a small-size and lightweight HMD is desired. However, in a technology in the related art described above, since the heat radiation properties were considered too much, the weight reduction was insufficient, and thus it was difficult to say that the mountability was excellent. Therefore, it is desired to propose a new technology in which the influence of heat can be reduced without increasing its weight as much as possible.

### SUMMARY

An advantage of some aspects of the invention is to provide a wearable apparatus capable of radiating heat from a display panel while suppressing an increase in weight.

According to an aspect of the invention, there is provided a wearable apparatus including a display panel in which a display portion is formed on a first face of a substrate, a housing, and a panel frame supporting the display panel and transferring heat from the display panel to the housing.

In the configuration according to the aspect of the invention, it is possible to release heat generated in the display panel to the housing by the panel frame. Therefore, it is possible to suppress an occurrence of a malfunction such as a degradation in characteristics due to heat in the display panel by suppressing the heat generation of the display panel.

Therefore, since the heat radiation of the display panel is performed using the panel frame supporting the panel, it is possible to provide a display apparatus capable of radiating heat from a display panel while suppressing an increase in product weight, compared to a configuration in which a heat radiation member is separately used.

In the aspect, the panel frame may be configured so as to be arranged along a second face opposite to at least the first face of the substrate.

According to this configuration, it is possible to efficiently radiate heat of the second face on which heat is generated in the display panel.

In the aspect, the panel frame may be configured with a resin component including a heat conductive filler.

According to this configuration, it is possible to efficiently radiate heat of the display panel by the panel frame while suppressing an increase in weight.

In the aspect, the panel frame may be configured with a metal member.

According to this configuration, it is possible to efficiently radiate heat of the display panel by the panel frame.

In the aspect, the display panel may be configured so as to be supported by the panel frame through a heat conductive adhesive, a heat radiation sheet, or a heat radiation grease.

According to this configuration, it is possible to efficiently radiate heat of the display panel.

In the aspect, the housing may include a temple portion made of metal and the panel frame may be configured so as to be connected to the temple portion through a heat conductive adhesive, a heat radiation sheet, or a heat radiation grease.

According to this configuration, it is possible to efficiently radiate heat of the display panel to the temple portion.

In the aspect, the wearable apparatus may be configured so as to further include an optical member making an image from the display panel visually recognizable toward eyes of an observer and a frame holding the optical member and having heat conductivity.

According to this configuration, it is possible to radiate heat of the display by transmitting heat of the display panel to the frame for an optical member.

In the aspect, the frame for an optical member may be configured so as to be connected to the temple portion through a heat conductive adhesive, a heat radiation sheet, or a heat radiation grease.

According to this configuration, it is possible to dissipate heat from the frame for an optical member using the temple portion made of metal configuring the housing.

In the aspect, the frame for an optical member may be configured so as to be connected to the housing through a heat conductive adhesive.

According to this configuration, for example, even in a case where heat is transmitted from the display panel to the frame for an optical member, it is possible to radiate heat from the frame for an optical member to the housing. Therefore, since an increase in temperature of the frame for an optical member is suppressed, it is possible to radiate heat from the display panel side to the frame for an optical member.

In the aspect, the housing may include a heat conducting portion having heat conductivity and the panel frame may be configured so as to be connected to the heat conducting portion through a heat conductive adhesive, a heat radiation sheet, or a heat radiation grease.

According to this configuration, it is possible to efficiently radiate heat from the housing.

In the aspect, the heat conducting portion may be configured so as to contain a heat conductive filler.

According to this configuration, it is possible to efficiently radiate heat from the heat conducting portion.

In the aspect, the display panel may be configured so as to include a semiconductor substrate.

According to this configuration, it is possible to enhance the heat radiation properties of the display panel itself.

In the aspect, the display panel may be configured with a micro display.

According to this configuration, it is possible to provide an apparatus in which an increase in weight is suppressed.

### BRIEF DESCRIPTION OF THE DRAWINGS

The invention will be described with reference to the accompanying drawings, wherein like numbers reference like elements.

FIG. 1 is a view illustrating a usage form of an HMD according to a first embodiment.

FIG. 2 is a view illustrating a schematic configuration of the HMD according to the first embodiment.

FIG. 3 is a plane view illustrating a schematic configuration of a display panel including the HMD according to the first embodiment.

FIG. 4 is an exploded perspective view illustrating a heat radiation structure of the display panel according to the first embodiment.

FIG. 5 is a plane view illustrating the heat radiation structure of the display panel according to a second embodiment.

FIG. 6 is an exploded perspective view illustrating the heat radiation structure of the display panel according to a third embodiment.

### DESCRIPTION OF EXEMPLARY EMBODIMENTS

Hereinafter, embodiments of the invention will be described in detail with reference to drawings.

Meanwhile, as to the drawings used for descriptions described above, there are some cases where characteristic parts are enlarged and illustrated for convenience in order to make characteristics easier to understand, and a dimension ratio of each constituent element or the like is not necessarily the same as an actual one.

In the embodiment, as a configuration according to an embodiment of a wearable apparatus, a head mount display (hereinafter, referred to as an HMD) having a glasses-like appearance will be given as an example. The HMD can make an image light by a virtual image to be visually recognized with respect to an observer or a user mounting the display apparatus and can make an observer visually recognize or observe an external image by see-through.

### First Embodiment

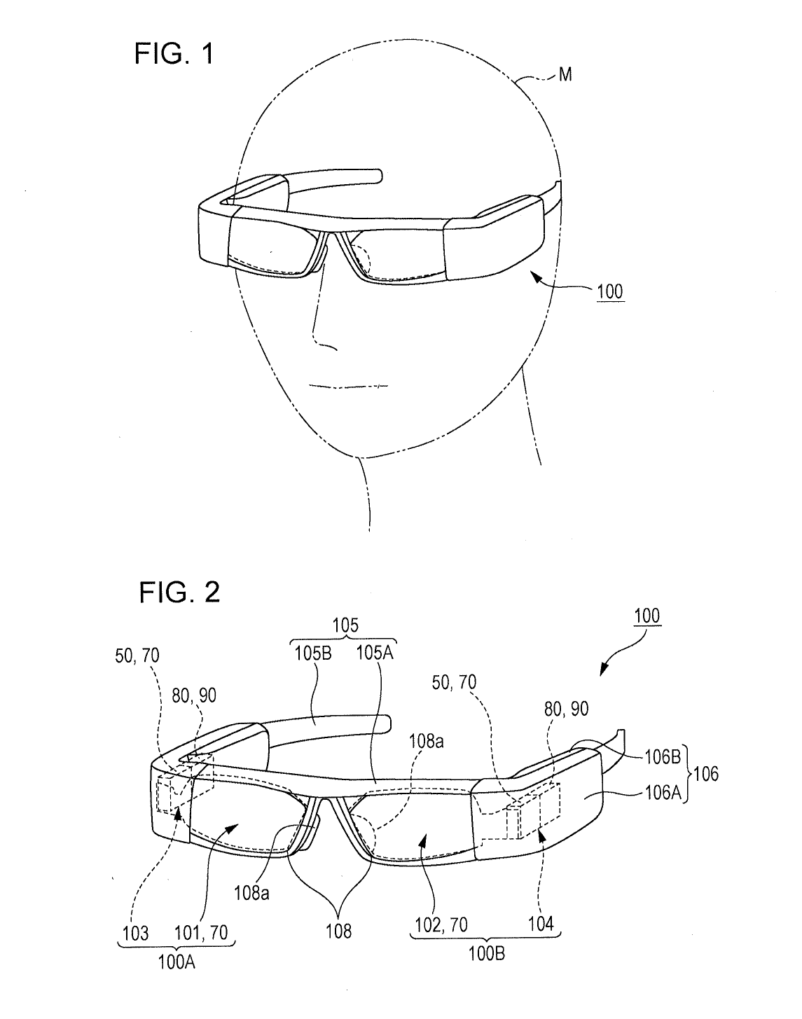

FIG. 1 is a view illustrating a usage form of an HMD 100. As shown in FIG. 1, the HMD 100 of the embodiment is used by being mounted on a head part of an observer M.

FIG. 2 is a view illustrating a schematic configuration of the HMD 100.

As shown in FIG. 2, the HMD 100 includes a first optical member 101 and a second optical member 102 covering a front of eyes of the observer so as to be able to see through, a first image forming portion 103 and a second image forming portion 104, and a housing 105.

The first optical member 101 and the second optical member 102 are circular arc-shaped members curved so as to be along a face of the observer and respectively include a prism portion for guiding light and seeing through and a light transmitting portion for seeing through. The first optical member 101 and the second optical member 102 are formed of a resin material showing high light transmitting properties in a visible region and are molded, for example, by pouring a thermoplastic resin into a metal mold to be solidified. In the first optical member 101 and the second optical member 102, the prism portion makes possible to wave-guide and emit the image light and makes possible to see through an external light and the light transmitting portion has high light transmitting properties in a visible region.

Here, a first display device 100A in which the first optical member 101 and the first image forming portion 103 on the left side in FIG. 1 are combined, forms a virtual image for a right eye and independently functions as a virtual image display device. In addition, a second display device 100B in which the second optical member 102 and the second image forming portion 104 on the right side in FIG. 1 combined, forms a virtual image for a left eye and also independently functions as a virtual image display device.

The housing 105 is a long and narrow plate-like member which is bent and is curved in a U shape. The housing 105 holds the first optical member 101 and the second optical member 102, and the first image forming portion 103 and the second image forming portion 104. The housing 105 includes a frame 105A, a temple portion 105B extending backward from both right and left ends of the frame 105A, and an exterior component 106. The frame 105A and the temple portion 105B is configured with a component made of metal such as aluminum or magnesium excellent in heat radiation properties.

The frame 105A holds the first optical member 101 and the second optical member 102 in an aligned state at a predetermined position. The temple portion 105B holds the first image forming portion 103 and the second image forming portion 104 in an aligned state at a predetermined position. Meanwhile, the temple portion 105B may have a hinge structure and in this case, it becomes possible to fold the temple portion 105B.

The exterior component 106 stores the first image forming portion 103 and the second image forming portion 104 in the inside thereof and covers a part of the temple portion 105B. The exterior component 106 includes an external face side component 106A and an internal face side component 106B and a part of the housing 105 is configured by these being fitted with each other.

In the embodiment, the first image forming portion 103 and the second image forming portion 104 are respectively fixed to the temple portion 105B in an aligned state with respect to the first optical member 101 and the second optical member 102.

Protectors 108 for protecting the lower side parts of the first and second optical members 101 and 102 are provided on the frame 105A. Pad-like nose pad members 108a are respectively formed on the protectors 108. The protector 108 is a long and narrow plate-like member which is bent in a two-stage crank shape and is an integrated component formed of a metal material or a resin material.

Here, the first display device 100A and the second display device 100B will be described. Meanwhile, since the first display device 100A and the second display device 100B have the same configuration, description will be given by giving the first display device 100A as an example here.

The first display device 100A includes a projection fluoroscopic device 70 which is an optical system for projection and a display panel 80 forming video light. The projection fluoroscopic device 70 has a role of projecting an image formed by the first image forming portion 103 to the eyes of the observer as a visual image. The projection fluoroscopic device 70 includes the first optical member 101 and a projection lens 50 for image formation. The projection lens 50 of the projection fluoroscopic device 70 and the display panel 80 forming an image pattern for display configure the first image forming portion 103.

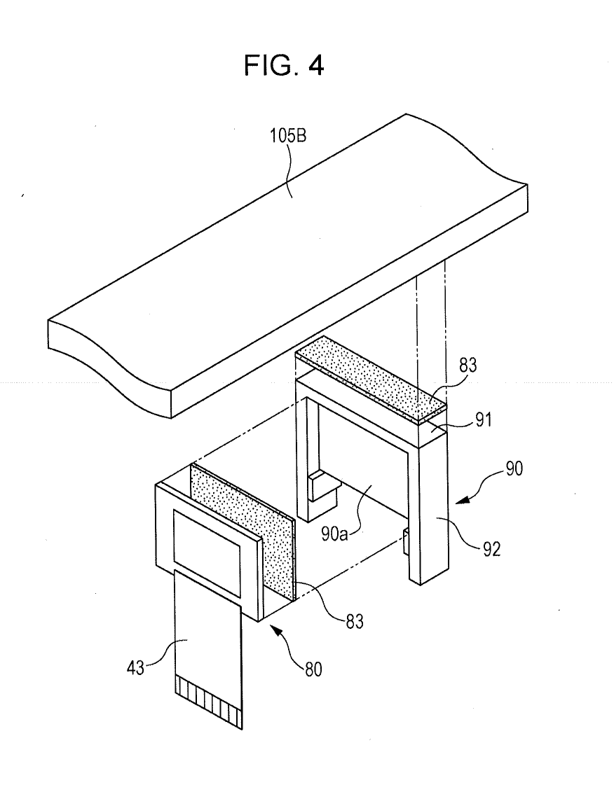

The projection lens 50 is directly fixed to the temple portion 105B utilizing its barrel (not shown). In such a fixation, the upper surface of the barrel is contact with the lower surface of the temple portion 105B to achieve alignment. In addition, as to the first optical member 101, a light entering part thereof is optically connected to a light emitting face side of the barrel. Accordingly, light is successfully led from the projection lens 50 into the first optical member 101. Meanwhile, the display panel 80 is held in the barrel of the projection lens 50 through a panel frame 90 described later (refer to FIG. 4). Accordingly, the display panel 80 is arranged in an aligned state with respect to projection lens 50.

Meanwhile, the projection fluoroscopic device 70 and the display panel 80 are also included in the second display device 100B. The projection fluoroscopic device 70 includes the second optical member 102 and the projection lens 50. The projection lens 50 and the display panel 80 configures the second image forming portion 104.

In the embodiment, the display panel 80 which is a constituent element of the first image forming portion 103 or the second image forming portion 104 is configured with a micro display. Specifically, the display panel 80 is configured with an organic EL device in which a plurality of pixel circuits, a driving circuit driving the pixel circuits, and the like are formed on a semiconductor substrate such as silicon.

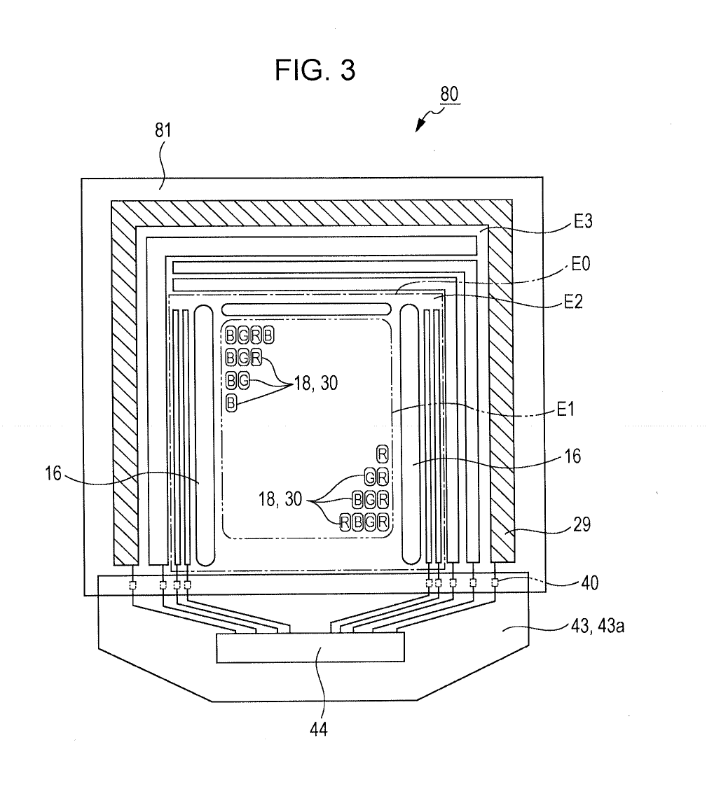

FIG. 3 is a plane view illustrating a schematic configuration of the display panel 80. As shown in FIG. 3, the display panel 80 (the organic EL device) has an element substrate 81. A display region E0 (in a figure, shown by a dash-dot line) and a non-display region E3 on the outside of the display region E0 are provided on the element substrate 81. The display region E0 has an actual display region E1 (in a figure, shown by a dash-double dot line) and a dummy region E2 surrounding the actual display region E1. The display panel 80 employs a top emission system in which light emitted from the organic EL element 30 is transmitted through a color filter and is taken out from a counter substrate (not shown) side. Therefore, the counter substrate is a transparent substrate such as, for example, a glass. On the other hand, the element substrate 81 is not necessary to be transparent and is configured with, for example, a silicon substrate in the embodiment. Accordingly, heat of the organic EL element 30 is efficiently taken out to the outside through the element substrate 81 as described later.

A sub pixel 18 is arranged in a matrix shape as a light-emitting pixel in the actual display region E1. The sub pixel 18 includes the organic EL element 30 as a light-emitting element and is configured so as to obtain light emission of any color of blue (B), green (G), and red (R) accompanying an action of a transistor for switching and a transistor for driving (not shown).

In the embodiment, the sub pixel 18 is arranged in a so-called stripe system in which the sub pixel 18 in which light emission of the same color is obtained is arrayed in a first direction and the sub pixel 18 in which light emission of different color is obtained is arrayed in a second direction intersecting with (orthogonal to) the first direction. Hereinafter, description will be given by respectively setting the first direction and the second direction to a Y direction and an X direction. Meanwhile, the arrangement of the sub pixel 18 in the element substrate 81 is not limited to a stripe system and may be a mosaic system or a delta system.

In the dummy region E2, peripheral circuits for mainly making the organic EL element 30 of each sub pixel 18 emit light are provided. For example, a pair of scanning line driving circuits 16 extending in the Y direction are provided at a position interposing the actual display region E1 in a horizontal direction in FIG. 3.

A flexible substrate (hereinafter, referred to as an FPC) 43 for obtaining electrical connection to an external driving circuit, is connected to one side part (a lower side part in the figure) parallel to a horizontal direction of the element substrate 81. An 1044 for driving which is connected to the peripheral circuits on the element substrate 81 side is implemented on a surface 43a of the FPC 43 through a wiring of the FPC 43.

A wiring 29, a terminal portion 40, and the like, for example, for applying a potential to the counter electrode (not shown) of the organic EL element 30 of each sub pixel 18, are formed between the display region E0 and an outer edge of the element substrate 81, that is, in non-display region E3. The wiring 29 is provided on the element substrate 81 so as to surround the display region E0 except the side part of the element substrate 81 to which the FPC 43 is connected. The terminal portion 40 is formed on the side part of the element substrate 81 to which the FPC 43 is connected.

In addition, the display panel 80 employs a configuration of sealing the organic EL element 30 in the inside in order to protect the display panel 80 from oxygen in the atmosphere, water, or the like. The display panel 80 makes a current flow to the organic EL element 30 to emit light, however, since the display panel 80 can not convert all applied electric power into light, heat is generated. There is a risk of a problem in which the light emitting characteristics are changed due to the influence of heat when the display panel 80 is used for a long time in a state in which heat is generated, occurs.

In particular, since a configuration in which the display panel 80 (the first image forming portion 103 or the second image forming portion 104) is covered by the exterior component 106, is employed in the HMD 100, the retention of heat as described above easily occurs. In order to suppress the influence of heat and obtain stable image display characteristics, it is important to efficiently radiate heat generated in the display panel 80 to the outside.

The HMD 100 of the embodiment was configured so as to radiate heat generated in the display panel 80 to the outside by including the panel frame which supports the display panel 80 and transfers heat from the display panel 80 to the housing 105, with respect to such a problem.

Specifically, in the embodiment, the panel frame is held in the display panel 80. Hereinafter, the heat radiation structure of the display panel 80 using the panel frame will be described.

FIG. 4 is an exploded perspective view illustrating the heat radiation structure of the display panel 80. In order to make the figure easy to view, FIG. 4 is set to a state in which the exterior component 106 is taken out and the display panel 80 is exposed.

As shown in FIG. 4, in the embodiment, the display panel 80 is supported by the panel frame 90. The panel frame 90 is configured with a metal component such as, for example, aluminum or magnesium.

The panel frame 90 has a supporting face 90a supporting a back face (a second face) 81a opposite to a front face (a first face) of the element substrate 81 (the display panel 80) on which the display region E0 (refer to FIG. 3) is formed. The panel frame 90 further holds a side end face of the element substrate 81.

In the display panel 80, the entire back face 81a of the element substrate 81 is supported by the supporting face 90a of the panel frame 90. The back face 81a and the supporting face 90a are adhered to each other through a heat conductive adhesive 83. The heat conductive adhesive 83 contains a filler of, for example, silicon oxide, aluminum oxide, or the like.

An upper plate portion 91 of the panel frame 90 is adhered to a lower face of the temple portion 105B through the heat conductive adhesive 83. As to the temple portion 105B, at least the connection part to the panel frame 90 is a flat face. Accordingly, the contact area of the panel frame 90 and the temple portion 105B is sufficiently secured.

Meanwhile, a heat radiation sheet or a heat radiation grease may be used for the connection of the panel frame 90 and the display panel 80 or the connection of the panel frame 90 and the temple portion 105B, in addition to the heat conductive adhesive 83. In addition, in a case where an adhesive force of the heat conductive adhesive 83 is sufficient and the display panel 80 is surely capable of being supported by the supporting face 90a, the panel frame 90 may be configured without holding a side end face of the display panel 80.

The FPC 43 is pulled out from the display panel 80 in a state of being supported by the panel frame 90 to downward and an electric power is supplied with respect to the display panel 80 by a tip part being connected to a power source portion (not shown).

As to the HMD 100 of the embodiment, in the first image forming portion 103 and the second image forming portion 104, the image light emitted from the display panel 80 is guided in the first optical member 101 and the second optical member 102 through the projection lens 50. The image light which is passed through the predetermined faces of the first optical member 101 and the second optical member 102 enters pupils of eyes of the observer as a substantially parallel luminous flux. That is, the observer can observe an image formed on the display panel 80 by the image light as a visual image. In addition, the observer can observe an external image through the first optical member 101 and the second optical member 102.

When the HMD 100 displays the image, the display panel 80 generates heat. In the embodiment, since the display panel 80 includes the element substrate 81 formed of a silicon substrate excellent in heat conductivity, heat of the display panel 80 is transmitted to the element substrate 81. Heat of the element substrate 81 is transferred to the supporting face 90a of the panel frame 90 which is adhered to the back face 81a of the element substrate 81.

In the panel frame 90, since the supporting face 90a is connected to the entire back face 81a of the display panel 80 (the element substrate 81), it is possible to efficiently take out heat of the display panel 80. Heat which is transmitted to the panel frame 90 (the supporting face 90a), is transmitted to the temple portion 105B through the upper plate portion 91 and the heat conductive adhesive 83 and is radiated from the temple portion 105B into the atmosphere.

As described above, according to the HMD 100 of the embodiment, heat is radiated to the outside by heat generated in the display panel 80 being conducted to the temple portion 105B (the housing) through the panel frame 90. Therefore, it is possible to provide the display apparatus having high reliability in which stable display characteristics can be obtained over a long time by reducing the retention of heat in the organic EL element 30.

In addition, since the HMD 100 is mounted on the head part of the observer, it is important to suppress the product weight. Also, regarding this, since the panel frame 90 supporting the display panel 80 is utilized as a heat radiation member, it is possible to suppress an increase in apparatus weight, compared to a structure in which the heat radiation member is separately provided. Therefore, it is possible to provide the HMD 100 having high reliability in which the heat radiation of the display panel 80 can be performed while suppressing an increase in apparatus weight.

In addition, since the display panel 80 which is configured with the micro display is mounted on the HMD 100, the HMD 100 becomes an HMD in which the miniaturization and the weight reduction are achieved.

### Second Embodiment

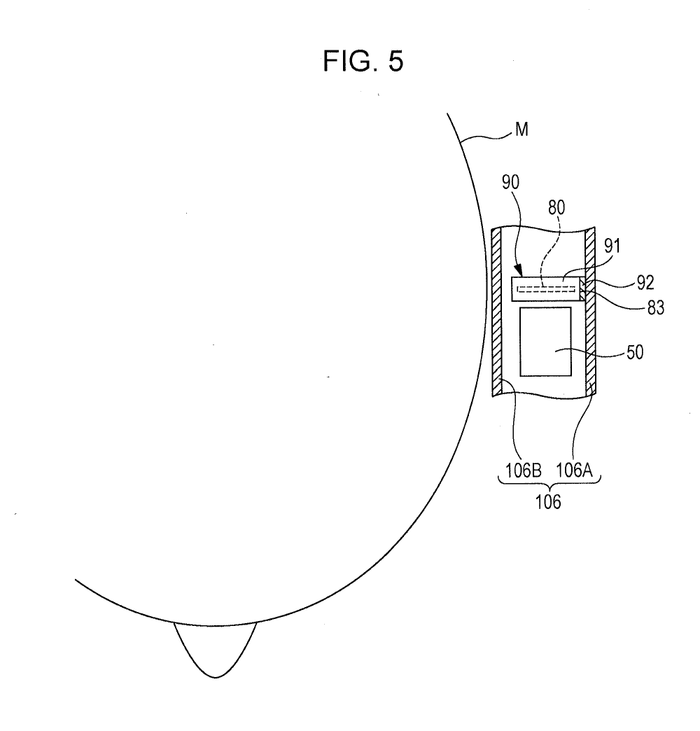

Next, another form of the heat radiation structure of the display panel 80 as a second embodiment will be described. FIG. 5 is a plane view illustrating the heat radiation structure of the display panel 80 according to the embodiment. The difference between the embodiment and the first embodiment is the destination of the heat radiation in the panel frame 90 and configurations other than that are common. Therefore, in the following description, as to parts equivalent to that of the embodiment described above, description thereof will be omitted and the same signs will be written in the drawings.

In the embodiment, the panel frame radiates heat generated in the display panel 80 to the outside by transferring heat to the exterior component 106 configuring a part of the housing 105 of the HMD 100.

Specifically, one of a pair of side plate portions 92 of the panel frame 90 is connected to an inner face of the external face side component 106A through the heat conductive adhesive 83. At least the external face side component (the heat conducting part) 106A among the exterior component 106 is configured with a resin material containing the heat conductive filler. As to the external face side component 106A, at least the connection part to the side plate portion 92 is a flat face. Accordingly, the contact area of the panel frame 90 and the temple portion 105B is sufficiently secured.

Heat generated in the display panel 80 is transferred to the inside of the element substrate 81 and then is transmitted to a side end face 81b. In the embodiment, the side plate portion 92 of the panel frame 90 directly or indirectly (through the heat conductive adhesive 83, the heat radiation sheet, or the heat radiation grease) comes into contact with the side end face of the element substrate 81.

Therefore, heat generated in the display panel 80 is transmitted to the side plate portion 92 of the panel frame 90 through the side end face 81b of the element substrate 81 and is transferred to the external face side component 106A through the side plate portion 92 and the heat conductive adhesive 83. Then, heat generated in the display panel 80 is radiated from the external face side component 106A to the atmosphere.

In addition, heat generated in the display panel 80 is transferred to the inside of the element substrate 81, is transmitted to the back face 81a, and is transferred to the supporting face 90a of the panel frame 90. Heat which is transferred to the supporting face 90a is transmitted to the side plate portion 92 and is transmitted to the external face side component 106A through the side plate portion 92 and the heat conductive adhesive 83.

Here, the external face side component 106A is different from the internal face side component 106B and does not come into contact with a face of the observer mounting the HMD. Therefore, even in a case where heat is radiated from the panel frame 90 to the exterior component 106, an occurrence of discomfortable feeling by making the observer M feel heat is prevented.

As described above, according to the embodiment, it is possible to radiate heat to the outside by conducting heat generated in the display panel 80 to the exterior component 106 (the housing) by the panel frame 90. In addition, since the panel frame 90 conducts heat with respect to the external face side component 106A closest to the side plate portion 92 of the panel frame 90 in which heat is transferred from the side end face 81b of the element substrate 81 which becomes a heat source, it is possible to efficiently radiate heat generated in the display panel 80 to the outside.

Therefore, it is possible to provide the HMD having high reliability in which the retention of heat in the organic EL element 30 is reduced and stable display characteristics can be obtained over a long time.

### Third Embodiment

Next, another form of the heat radiation structure of the display panel 80 as a third embodiment will be described. The difference between the embodiment and the first embodiment is the heat radiation of the display panel 80 and configurations other than that are common. Therefore, in the following description, as to parts equivalent to that of the embodiment described above, description thereof will be omitted and the same signs will be written in the drawings.

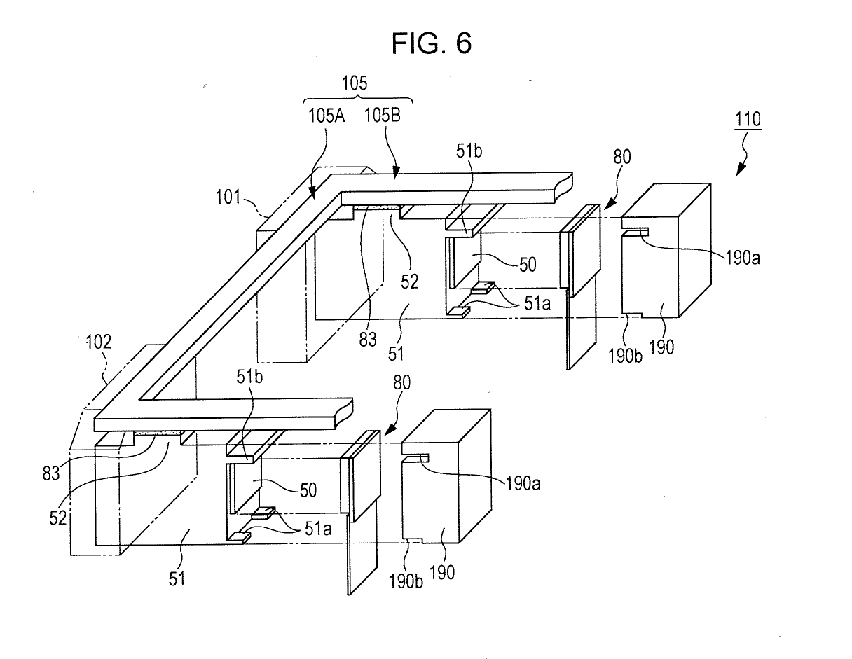

FIG. 6 is an exploded perspective view illustrating the heat radiation structure of the display panel 80 according to the embodiment.

In the embodiment, as shown in FIG. 6, in an HMD 110 in the embodiment, the projection lens 50 and a panel frame 190 are unitized. Specifically, the projection lens (the optical member) 50 is held on a barrel (a frame for an optical member) 51. The barrel 51 has a pair of lower side convex portions 51a and an upper side convex portion 51b. Since the barrel 51 is configured with a resin molded component containing, for example, the heat conductive filler, the barrel 51 has the heat conductivity as a whole.

The barrel 51 is fixed to the temple portion 105B through a fitting portion 52 which is provided on an upper face of the barrel 51 and in which the surface thereof is flat. As to the temple portion 105B, at least the connection part to the fitting portion 52 is a flat face. Accordingly, the contact area of the barrel 51 and the temple portion 105B is sufficiently secured.

In addition, the heat conductive adhesive 83 is arranged between the fitting portion 52 and the temple portion 105B. Accordingly, heat is successfully transferred from the barrel 51 to the temple portion 105B side. Meanwhile, the heat radiation sheet or the heat radiation grease may be used for the connection of the barrel 51 and the temple portion 105B, in addition to the heat conductive adhesive 83.

The panel frame 190 of the embodiment is configured with the resin molded component containing the heat conductive filler in the same way as the barrel 51 and has a lower side concave portion 190a corresponding to the lower side convex portion 51a of the barrel 51 and an upper side concave portion 190b corresponding to the upper side convex portion 51b of the barrel 51. The panel frame 190 supports the entire back face 81a of the element substrate 81 of the display panel 80 in the same way as the first embodiment.

The panel frame 190 holding the display panel 80 is integrated with the barrel 51 by respectively fitting the lower side concave portion 190a and the lower side convex portion 51a, and the upper side concave portion 190b and the upper side convex portion 51b. The panel frame 190 and the barrel 51 (a gap of fitting part) are fixed to each other by the heat conductive adhesive (not shown). Accordingly, heat of the display panel 80 is successfully transferred to the barrel 51 side through the panel frame 190.

In the embodiment, heat generated in the display panel 80 is transmitted to the panel frame 190 which is adhered to the back face of the element substrate 81. Since the panel frame 190 is integrated with the barrel 51 having heat conductivity, heat is transferred from the panel frame 190 to the barrel 51 side.

In the embodiment, since the fitting parts of the panel frame 190 and the barrel 51 (the lower side concave portion 190a and the lower side convex portion 51a, and the upper side concave portion 190b and the upper side convex portion 51b) are connected through the heat conductive adhesive, heat is efficiently transferred from the panel frame 190 to the barrel 51 side.

Heat which is transmitted to the barrel 51 is transferred to the inside of the barrel 51, is transmitted to the temple portion 105B through the fitting portion 52 and the heat conductive adhesive 83, and is radiated from the temple portion 105B to the atmosphere.

As described above, according to the HMD 110 of the embodiment, it is possible to radiate heat to the outside by taking out heat generated in the display panel 80 to the panel frame 190 and conducting heat to the temple portion 105B (the housing) through the barrel 51 thermally connected by being integrated with the panel frame 190.

Therefore, it is possible to provide the HMD having high reliability in which the retention of heat in the organic EL element 30 is reduced and stable display characteristics can be obtained over a long time.

Meanwhile, the invention is limited to the aspects of embodiments described above and changes can be appropriately made in a range without departing from the gist of the invention.

### Modification Example 1

For example, in the first and second embodiments, while a case in which the panel frame 90 is configured with the metal component is given as an example, the panel frame 90 may be configured with the resin molded component containing the heat conductive filler. In doing so, since a reduction in weight of the panel frame 90 is achieved, it is possible to realize a further reduction in weight of the HMD 100.

### Modification Example 2

In addition, in the third embodiment, while a case in which both of the panel frame 190 and the barrel 51 are configured with the resin molded component is given as an example, at least one of those may be configured with the metal component. For example, when the barrel 51 is configured with the metal component having high heat conductivity, it is possible to efficiently transfer heat to the panel frame 190 and the temple portion 105B. In addition, since the rigidity is enhanced by configuring with the metal member, it is possible to surely hold the panel frame 190 and the display panel 80. On the other hand, when the panel frame 190 is configured with the metal component having high heat conductivity, it is possible to efficiently take out heat of the display panel 80 and suppress an increase in temperature of the organic EL element 30.

### Modification Example 3

In addition, in the third embodiment, while the fitting portion 52 of the barrel 51 is fixed to the temple portion 105B, the fitting portion 52 of the barrel 51 may be connected to an inner face of the external face side component 106A as the second embodiment. In this case, heat generated in the display panel 80 is radiated to the outside by transferring heat to the exterior component 106 configuring a part of the housing 105 of the HMD 100. In this case, the fitting portion 52 may be provided not on the upper face of the barrel 51 but instead may be provided on the side face of the barrel 51 or may be provided on the lower face of the barrel 51.

### Modification Example 4

In the third embodiment and the modification thereof, while the fitting portion 52 of the barrel 51 is connected to the temple portion 105B or the inner face of the external face side component 106A, the panel frame 190 may be further connected to the temple portion 105B or the inner face of the external face side component 106A, in addition to this.

### Modification Example 5

In the embodiment, while the panel frame 90 has the supporting face 90a supporting the back face (the second face) 81a opposite to the front face (the first face) of the element substrate 81 (the display panel 80) on which the display region E0 (refer to FIG. 3) is formed and the panel frame 90 further holds the side end face of the element substrate 81, the panel frame 90 is not limited thereto and the panel frame 90 may be a panel frame in which at least a part of the supporting face 90a is omitted and which has the side end face of the element substrate 81.

The entire disclosure of Japanese Patent Application No.: 2014-162230, filed Aug. 8, 2014 is expressly incorporated by reference herein.

What is claimed is:

1. A wearable apparatus comprising:
a display panel in which a display portion is formed on a first face of a substrate;
a housing; and
a panel frame supporting the display panel and transferring heat from the display panel to the housing.

2. The wearable apparatus according to claim 1,
wherein the panel frame is arranged along a second face opposite to at least the first face of the substrate.

3. The wearable apparatus according to claim 1,
wherein the panel frame is configured with a resin component including a heat conductive filler.

4. The wearable apparatus according to claim 1,
wherein the panel frame is configured with a metal member.

5. The wearable apparatus according to claim 1,
wherein the display panel is supported by the panel frame through a heat conductive adhesive, a heat radiation sheet, or a heat radiation grease.

6. The wearable apparatus according to claim 1,
wherein the housing includes a temple portion made of metal, and
wherein the panel frame is connected to the temple portion through a heat conductive adhesive, a heat radiation sheet, or a heat radiation grease.

7. The wearable apparatus according to claim 6, further comprising:
an optical member making an image from the display panel visually recognizable toward eyes of an observer; and
a frame holding the optical member and having heat conductivity.

8. The wearable apparatus according to claim 7,
wherein the frame is connected to the temple portion through a heat conductive adhesive, a heat radiation sheet, or a heat radiation grease.

9. The wearable apparatus according to claim 7,
wherein the frame is connected to the housing through a heat conductive adhesive.

10. The wearable apparatus according to claim 1,
wherein the housing includes a heat conducting portion having heat conductivity, and
wherein the panel frame is connected to the heat conducting portion through a heat conductive adhesive, a heat radiation sheet, or a heat radiation grease.

11. The wearable apparatus according to claim 10,
wherein the heat conducting portion contains a heat conductive filler.

12. The wearable apparatus according to claim 1,
wherein the display panel includes a semiconductor substrate.

13. The wearable apparatus according to claim 1,
wherein the display panel is configured with a micro display.
